(19) United States
(12) Patent Application Publication
(10) Pub. No.: US 2026/0291491 A1
(43) Pub. Date: Sep. 24, 2026

(54) SWITCH CONTROL APPARATUS INCLUDING SWITCH CONTROL CIRCUIT AND POWER SUPPLY APPARATUS INCLUDING SWITCH CONTROL CIRCUIT

(71) Applicant: SAMSUNG SDI CO., LTD., Yongin-si (KR)

(72) Inventor: SUNGJUNG KIM, Yongin-si (KR)

(73) Assignee: SAMSUNG SDI CO., LTD., Yongin-si (KR)

(21) Appl. No.: 19/329,883

(22) Filed: Sep. 16, 2025

(30) Foreign Application Priority Data
Mar. 18, 2025 (KR) 10-2025-0034621

(51) Int. Cl. H03K 17/20; H02H 3/02; H03K 17/18; H03K 17/28

(52) U.S. Cl. CPC H03K 17/20; H02H 3/021; H03K 17/18; H03K 17/28

(57) ABSTRACT

Provided are a switch control apparatus including a switch control circuit and a power supply apparatus including the switch control circuit. The switch control apparatus includes a controller configured to generate a safety signal and an enable signal, a first logic circuit configured to receive the safety signal and the enable signal, and to generate a first reset signal, a timer circuit configured to receive each of the safety signal and the first reset signal, and to generate a second reset signal, and a latch circuit configured to receive each of the safety signal, the enable signal, and the second reset signal, and to generate a retain signal.

### CROSS-REFERENCE TO RELATED APPLICATIONS

This present application claims priority to and the benefit under 35 U.S.C. § 119(a)-(d) of Korean Patent Application No. 10-2025-0034621, filed on Mar. 18, 2025, in the Korean Intellectual Property Office, the entire disclosure of which is incorporated herein by reference.

### FIELD

The present disclosure relates to a switch control apparatus including a switch control circuit and a power supply apparatus including the switch control circuit.

### BACKGROUND

Electrical connectors and the like are employed as switches for controlling the electrical connection between a power source and a load. For example, in electric vehicles (EVs) and hybrid electric vehicles (HEVs), a high-voltage battery pack is configured with a plurality of secondary batteries to drive a motor, and power is supplied from the battery pack to the motor via an electrical connector.

The growing adoption of high-capacity battery packs has led to increased demand for safe and stable power supply systems, as well as for technologies that guarantee the reliable operation of switch control circuits to ensure the safety of the power supply systems.

The background technology described herein is technical information that the inventor possessed for deriving the present disclosure or acquired in the process of deriving the present disclosure, and cannot necessarily be considered as publicly known technology disclosed to the general public prior to the application for the present disclosure.

### SUMMARY

The present disclosure is directed to providing a switch control apparatus including a switch control circuit and a power supply apparatus including the switch control circuit. The problems to be solved by the present disclosure are not limited to the problems mentioned herein, and other problems and advantages of the present disclosure that are not mentioned may be understood by the following description and more clearly understood by embodiments of the present disclosure. In addition, it will be appreciated that the problems and advantages to be solved by the present disclosure may be implemented by means and combinations thereof defined in claims.

According to aspects of the present disclosure, there is provided a switch control apparatus including a controller configured to generate a safety signal and an enable signal, a first logic circuit configured to receive the safety signal and the enable signal, and to generate a first reset signal, a timer circuit configured to receive each of the safety signal and the first reset signal, and to generate a second reset signal, and a latch circuit configured to receive each of the safety signal, the enable signal, and the second reset signal, and to generate a retain signal.

According to embodiments, the first logic circuit may be further configured to output the first reset signal indicating an active state when at least one of the safety signal and the enable signal indicates an inactive state.

According to embodiments, the timer circuit may be further configured to receive the safety signal after receiving the first reset signal when the enable signal indicates an active state and the safety signal indicating the active state transitions to an inactive state. According to embodiments, the switch control apparatus may further include a delay circuit configured to transmit a delayed safety signal to the timer circuit.

According to embodiments, the controller may include a main controller configured to generate the enable signal, and an auxiliary controller configured to generate the safety signal based on a state of the main controller.

According to embodiments, the first reset signal may cause the timer circuit to be set to a reset state, and the second reset signal may cause the latch circuit to be set to the reset state.

According to embodiments, the timer circuit may be further configured to output the second reset signal at a point in time after a preset period of time has elapsed from a point in time at which the safety signal is received.

According to embodiments, the latch circuit may be further configured to output the retain signal from a point in time at which the safety signal is received until a point in time at which the second reset signal is received.

According to embodiments, the switch control apparatus may further include a second logic circuit configured to receive the enable signal and the retain signal, and to output a control signal for controlling opening and closing of a switch.

According to embodiments, the controller may be further configured to diagnose the switch control apparatus based on the retain signal.

According to aspects of the present disclosure, there is provided a power supply apparatus including a power source, a switch configured to electrically connect or disconnect the power source to or from at least one load, a controller configured to generate a safety signal and an enable signal, a first logic circuit configured to receive the safety signal and the enable signal, and to generate a first reset signal, a timer circuit configured to receive each of the safety signal and the first reset signal, and to generate a second reset signal, a latch circuit configured to receive each of the safety signal, the enable signal, and the second reset signal, and to generate a retain signal, and a second logic circuit configured to receive the enable signal and the retain signal, and to output a control signal for controlling opening and closing of the switch.

According to embodiments, the first logic circuit may be further configured to output the first reset signal indicating an active state when at least one of the safety signal and the enable signal indicates an inactive state.

According to embodiments, the timer circuit may be further configured to receive the safety signal after receiving the first reset signal when the enable signal indicates an active state and the safety signal indicating the active state transitions to an inactive state. According to embodiments, the power supply apparatus may further include a delay circuit configured to transmit a delayed safety signal to the timer circuit.

According to embodiments, the controller may include a main controller configured to generate the enable signal, and an auxiliary controller configured to generate the safety signal based on a state of the main controller.

According to embodiments, the first reset signal may cause the timer circuit to be set to a reset state, and the second reset signal may cause the latch circuit to be set to the reset state.

In embodiments, the timer circuit may provide a power source apparatus that outputs the second reset signal at a point in time when a preset period of time has elapsed since the point in time at which the safety signal is received.

According to embodiments, the latch circuit may be further configured to output the retain signal from a point in time at which the safety signal is received until a point in time at which the second reset signal is received.

According to embodiments, the controller may be further configured to diagnose the power supply apparatus based on the retain signal.

According to embodiments, there is provided a method of manufacturing a switch control apparatus including providing a controller configured to generate a safety signal and an enable signal, providing a first logic circuit configured to receive the safety signal and the enable signal, and to generate a first reset signal, providing a timer circuit configured to receive each of the safety signal and the first reset signal, and to generate a second reset signal, and providing a latch circuit configured to receive each of the safety signal, the enable signal, and the second reset signal, and to generate a retain signal.

According to embodiments, there is provided a method of manufacturing a power supply apparatus including providing a power source, providing a switch configured to electrically connect or disconnect the power source to or from at least one load, providing a controller configured to generate a safety signal and an enable signal, providing a first logic circuit configured to receive the safety signal and the enable signal, and to generate a first reset signal, providing a timer circuit configured to receive each of the safety signal and the first reset signal, and to generate a second reset signal, providing a latch circuit configured to receive each of the safety signal, the enable signal, and the second reset signal, and to generate a retain signal, and providing a second logic circuit configured to receive the enable signal and the retain signal, and to output a control signal for controlling opening and closing of the switch.

Other aspects, features, and advantages other than those described herein will become apparent from the following drawings, claims, and detailed description of the disclosure.

### BRIEF DESCRIPTION OF THE DRAWINGS

The following drawings attached to this disclosure are provided to illustrate embodiments according to the present disclosure and serve to further understand the technical idea of the present disclosure together with specific details for carrying out the present disclosure, and thus the present disclosure should not be interpreted as being limited only to the matters described in the drawings in which:

FIG. 1 is an exemplary diagram for schematically describing a power supply system according to embodiments;

FIG. 2 is an exemplary diagram for describing a controller according to embodiments;

FIG. 3 is an exemplary diagram for schematically describing a switch control circuit;

FIG. 4 is a circuit diagram of a switch control circuit including a logic circuit configured to output a reset signal according to embodiments;

FIG. 5 is a circuit diagram of a switch control circuit including a logic circuit and a delay circuit according to embodiments;

FIG. 6 is a circuit diagram of a switch control circuit including a logic circuit configured to receive an enable signal and a retain signal according to embodiments;

FIG. 7 is a circuit diagram of a switch control circuit according to embodiments;

FIG. 8 is an exemplary diagram for describing a normal operation of the switch control circuit of FIG. 7; and

FIG. 9 is an exemplary diagram for describing a diagnostic operation of the switch control circuit of FIG. 7.

### DETAILED DESCRIPTION

Advantages and features of the present disclosure, and methods of achieving the same will become clear with reference to the detailed description of embodiments taken in conjunction with the accompanying drawings. However, it should be understood that the present disclosure is not limited to the embodiments presented herein, but may be implemented in various other forms and includes all transformations, equivalents, and substitutes included in the spirit and scope of the present disclosure. The embodiments presented herein are provided to complete the present disclosure and to fully inform those skilled in the art to which the present disclosure belongs. In explaining the present disclosure, if it is determined that a detailed description of a related known technology may obscure the gist of the present disclosure, the detailed description will be omitted. Terms used herein are only used to describe particular embodiments, and are not intended to limit the present disclosure. Unless otherwise defined, all terms used herein have the same meaning as commonly understood by one having ordinary skill in the art to which the present disclosure belongs.

In the present specification, singular forms are intended to include plural forms as well, unless the context clearly indicates otherwise. Further, the terms “include” or “have” should be understood to be intended to designate that illustrated features, numbers, steps, operations, components, parts or combinations thereof exist and not to preclude the existence of one or more different features, numbers, steps, operations, components, parts or combinations thereof, or the possibility of the addition thereof.

In addition, terms including ordinal numbers such as “first” or “second” used herein may be used to describe various components, but the components should not be limited by the terms. These terms are used only for the purpose of distinguishing one component from another component.

Phrases such as “in an embodiment,” “according to an embodiment” , “relating to an embodiment,” “according to an embodiment implementation,” and the like appearing in various places in the present specification are not necessarily all referring to the same embodiment. Further, throughout the specification, “embodiment” is a random division for easily describing the disclosure in the present disclosure, and each embodiment need not be mutually exclusive. For example, configurations mentioned for the purpose of describing one embodiment may be applied and implemented in other embodiments and may be changed and applied and implemented without departing from the idea and scope of the present disclosure.

Some embodiments of the present disclosure may be represented by functional block configurations and various processing operations. Some or all of these functional blocks may be implemented by various numbers of hardware and/or software configurations that perform particular functions. For example, the functional blocks of the present disclosure may be implemented by one or more microprocessors or by circuit configurations for a certain function.

For example, the functional blocks of the present disclosure may be implemented in various programming or scripting languages. The functional blocks may be implemented by algorithms executed in one or more processors. In addition, the present disclosure may employ conventional techniques for electronic environment setting, signal processing, and/or data processing. Terms such as “mechanism,” “element,” “means,” and “configuration” can be used broadly and are not limited to mechanical and physical configurations. In addition, terms such as “unit,” “-or/-er,” and “module” denote a unit that processes at least one function or operation, which may be implemented in hardware or software, or implemented in a combination of hardware and software.

In addition, a connection line or a connection member between components shown in the drawings is merely a functional connection and/or a physical or circuit connection. In an actual device, connections between components may be represented by various functional connections, physical connections, or circuit connections that are replaceable or added.

In addition, some components in the drawings may be shown to be exaggerated in size or proportion. Moreover, components shown in one drawing may not be shown in other drawings.

Hereinafter, the present disclosure will be described in detail with reference to the accompanying drawings.

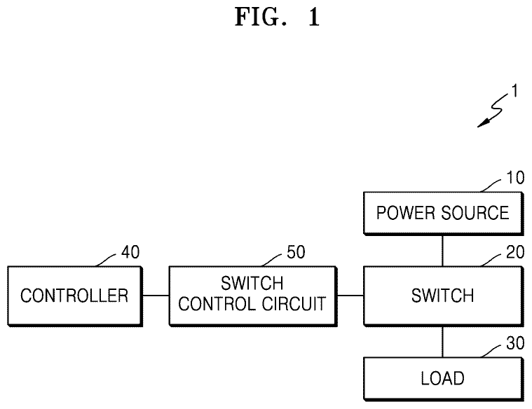

FIG. 1 is an exemplary diagram for schematically describing a power supply system according to embodiments;

Referring to FIG. 1, a power supply system 1 may include a power source 10, a switch 20, a load 30, a controller 40, and a switch control circuit 50. The power supply system 1 according to embodiments may be applied to various devices such as electric vehicles (EVs), hybrid electric vehicles (HEVs), electric bicycles (E-Bikes), power tools, energy storage systems (ESS), uninterruptible power supplies (UPS), portable computers, mobile phones, portable audio devices, and/or portable video devices, but the present disclosure is not limited thereto.

In embodiments, the switch 20 is connected between the power source 10 and the load 30, and provides or interrupts an electrical connection between the power source 10 and the load 30. In an ON (closed) state, the switch 20 electrically connects the power source 10 to the load 30, and in an OFF (open) state, the switch 20 electrically disconnects the power source 10 from the load 30.

In embodiments, the power source 10 may include a battery pack configured as a single unit by connecting a plurality of battery cells. In embodiments, the load 30 may include a motor that provides a rotational force using power supplied from the power source 10, or a power conversion circuit that converts power supplied from the power source 10 into power required by various circuit components, but the present disclosure is not limited thereto.

The switch 20 according to embodiments may include a physical switch or a relay that physically controls an electrical connection. For example, the switch 20 may include a magnetic contactor (MC) whose opening and closing operations are controlled by an electromagnet. The switch 20 according to embodiments may include a field-effect transistor that controls an electrical connection through a gate voltage. In embodiments, at least one switch 20 may be provided between the power source 10 and the load 30 to ensure stable and safe power supply to the load 30.

In the present disclosure, a power supply apparatus refers to a device that supplies power to the load 30. In embodiments, the power supply apparatus may include the power source 10 and a switch control apparatus. The power supply apparatus may include a plurality of components used to supply power to the load 30. The power supply apparatus may include a battery pack equipped with a battery management system (BMS), a power bank for a portable electronic device, or the like, but the present disclosure is not limited thereto.

In the present disclosure, the switch control apparatus refers to a device that manages and controls the state of the switch 20. In embodiments, the switch control apparatus may include the controller 40 and the switch control circuit 50. In the present disclosure, the controller 40 refers to at least one electronic device that controls the switch control circuit 50. The controller 40 according to embodiments may control the switch control circuit 50 by generating at least one signal.

In embodiments, the switch control apparatus may control the state of the switch 20 to an ON state or an OFF state. For example, the switch control apparatus may apply a control signal to a switch driver for the switch 20 to control the state of the switch 20 to either an ON or OFF state, and the switch driver may control the switch 20 so that the switch 20 has a state corresponding to the control signal. In some embodiments, the switch driver may be included on the side of the switch control circuit 50 or on the side of the switch 20, as shown in FIG. 1.

In embodiments, the switch control apparatus may include a battery management system for the power source 10, which is implemented as a battery pack. The switch control apparatus may generate a control signal for controlling the switch 20 based on the state of the power source 10, the switch control apparatus, or the load 30.

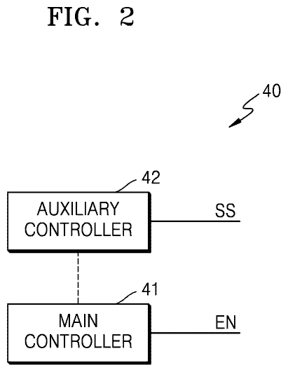

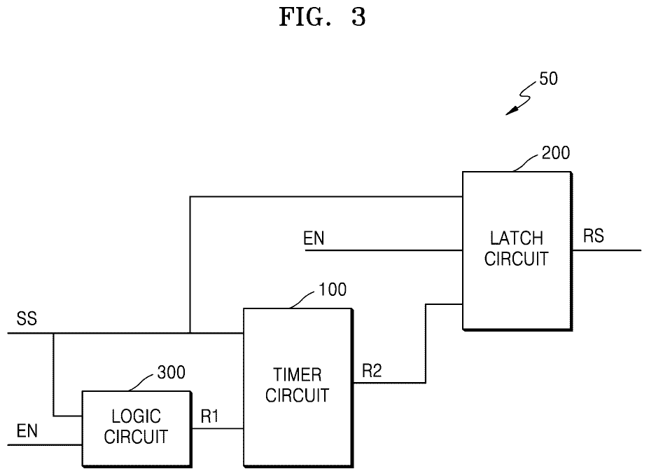

Hereinafter, with reference to FIG. 2, a specific implementation example of the controller 40 according to embodiments will be described in detail, and with reference to FIG. 3, a specific implementation example of the switch control circuit 50 according to embodiments will be described in detail.

FIG. 2 is an exemplary diagram for describing the controller according to embodiments. Referring to FIG. 2, the controller 40 may generate a safety signal SS and an enable signal EN.

In embodiments, the controller 40 may include at least one memory and at least one processor. The memory is hardware that stores various types of data processed within the controller 40, and may store programs for performing various operations, processing, and control by the at least one processor.

For example, the memory may include a random access memory (RAM) such as a dynamic random access memory (DRAM) or a static random access memory (SRAM), a read-only memory (ROM), and an electrically erasable programmable read-only memory (EEPROM), a CD-ROM, Blu-ray or other optical disk storage, a hard disk drive (HDD), a solid state drive (SSD), or flash memory.

The processor controls overall operations of the controller 40. For example, the processor may control the overall operations of the controller 40 by executing programs stored in the memory. For example, the processor may control the controller 40 to generate at least one of the safety signal SS and the enable signal EN by determining whether respective signal generation conditions are satisfied.

At this time, the generation of signals such as the safety signal SS or the enable signal EN may include generating a signal in an active state (for example, a high state or a low state), as defined when a generation condition is satisfied, and generating a signal in an inactive state (for example, a low state or a high state), as defined when the generation condition is not satisfied.

The processor may be implemented by using at least one of an application specific integrated circuit (ASIC), a digital signal processor (DSP), a digital signal processing device (DSPD), a programmable logic device (PLD), a field programmable gate array (FPGA), a controller, a micro-controller, a microprocessor, and an electric unit for performing other functions.

In the present disclosure, the safety signal SS is a signal generated by the controller 40 to ensure safe operation of the switch 20, and may be generated when a potential hazard or abnormal condition is detected.

In embodiments, the controller 40 may generate the safety signal SS when a potential hazard or abnormal condition is detected in the controller 40. For example, the controller 40 may generate the safety signal SS when an abnormal condition is detected, such as when at least a part of the controller 40 experiences a fault or when at least a part of the controller 40 is reset. For example, the controller 40 may generate the safety signal SS in an active state when the controller 40 is operating in a normal state, and may generate the safety signal SS in an inactive state when a potential hazard or abnormal condition is detected in the controller 40.

In embodiments, the controller 40 may artificially generate the safety signal SS for diagnosis of the switch control circuit 50, even when no potential hazard or abnormal condition is detected in the controller 40.

In the present disclosure, the enable signal EN is a signal that instructs the switch driver to operate, and may be generated when the controller 40 directly controls the operation of the switch 20.

In embodiments, the controller 40 may generate the enable signal EN continuously to maintain the switch 20 in the ON state. In some embodiments, when an abnormal condition occurs, such as when at least a part of the controller 40 experiences a fault or is reset, the enable signal EN may not be normally generated and transmitted.

For example, the controller 40 may continuously generate the enable signal EN in an active state to maintain the switch 20 in the ON state, and may generate the enable signal EN in an inactive state when the enable signal EN cannot be normally generated and transmitted.

In embodiments, the controller 40 may include a main controller 41 that generates the enable signal EN and an auxiliary controller 42 that generates the safety signal SS based on the state of the main controller 41. In embodiments, the main controller 41 and the auxiliary controller 42 may each be implemented to include at least one processor.

In embodiments, the auxiliary controller 42 may manage power supply to the main controller 41 and monitor the state of the main controller 41 by performing communication with the main controller 41.

In embodiments, by monitoring the state of the main controller 41, the auxiliary controller 42 may generate the safety signal SS when an abnormal condition or fault occurs in the main controller 41. For example, the auxiliary controller 42 may generate the safety signal SS when no response is received from the main controller 41 for a certain period of time or more, as monitored by a watchdog timer.

In the present disclosure, various signals such as the safety signal SS and the enable signal EN may each include a signal having two or more states. In embodiments, the reception of a signal by each component of the switch control circuit 50 may indicate the reception of the signal in a specific state among a first state and a second state. For example, the reception of a signal by each component of the switch control circuit 50 may indicate the reception of the signal in a state defined as an active state. In this case, the active state may indicate a signal state corresponding to a state in which a specific function of a specific component is actively performed or enabled.

As an example, the reception of the safety signal SS by a certain component constituting the switch control circuit 50 may indicate the reception of the safety signal SS in a first state, when the first state of the safety signal SS is defined as indicating the active state for the certain component.

In an example that does not conflict with the herein-described example, the reception of the safety signal SS by another component constituting the switch control circuit 50 may indicate the reception of the safety signal SS in a second state, when the second state of the safety signal SS is defined as indicating the active state for the corresponding component.

FIG. 3 is an exemplary diagram for schematically describing the switch control circuit.

Referring to FIG. 3, the switch control circuit 50 according to embodiments may include a timer circuit 100 and a latch circuit 200.

In the present disclosure, the timer circuit 100 refers to a circuit that outputs a specific signal after a predetermined time delay when a preset condition is satisfied. For example, the preset condition may include receiving a specific type of signal having a specific state. The timer circuit 100 according to embodiments may be implemented by including at least one electronic element for implementing the herein-described function of the timer circuit 100.

In the present disclosure, the latch circuit 200 refers to a circuit that stores an input predetermined signal or stores and maintains the state of the input predetermined signal. For example, the latch circuit 200 may maintain the first state even after receiving a second state signal, subsequent to receiving a first state signal. The latch circuit 200 according to embodiments may be implemented by including at least one electronic element for implementing the herein-described function of the latch circuit 200.

In some embodiments, the switch control circuit 50 according to embodiments may further include a first logic circuit 300. The first logic circuit 300 according to embodiments may be configured to receive the safety signal SS and the enable signal EN, and to generate a first reset signal R1.

In this case, the first reset signal R1 refers to a signal for directly or indirectly resetting at least some of the components of the switch control circuit 50. For example, the first reset signal R1 may directly reset the timer circuit 100, and indirectly reset the latch circuit 200 by controlling the operation of the timer circuit 100 such that the timer circuit 100 generates a second reset signal R2.

In embodiments, the first logic circuit 300 may generate the first reset signal R1 based on the safety signal SS and the enable signal EN. For example, the first logic circuit 300 may generate the first reset signal R1 based on the reception status of at least one of the safety signal SS and the enable signal EN. As an example, the first logic circuit 300 may generate the first reset signal R1 when at least one of the safety signal SS and the enable signal EN is received.

As another example, the first logic circuit 300 may generate the first reset signal R1 when one of the safety signal SS and the enable signal EN fails to be received while both signals are expected to be received. As another example, the first logic circuit 300 may generate the first reset signal R1 in an inactive state when receiving both the safety signal SS and the enable signal EN in active states, and may generate the first reset signal R1 in an active state when receiving at least one of the safety signal SS and the enable signal EN in an inactive state.

In embodiments, the switch control circuit 50 may include the timer circuit 100 configured to receive each of the safety signal SS and the first reset signal R1 and to generate a second reset signal R2. For example, the switch control circuit 50 may include the timer circuit 100 configured to receive the safety signal SS, to further receive the first reset signal R1 from the first logic circuit 300, and to generate the second reset signal R2.

The timer circuit 100 according to embodiments may receive the safety signal SS generated by the controller 40 via a port corresponding to the safety signal SS, and may receive the first reset signal R1 generated by the first logic circuit 300 via a port corresponding to the first reset signal R1.

In embodiments, the timer circuit 100 may output the second reset signal R2 at a point in time after a preset period of time has elapsed from a point in time at which the safety signal SS is received. For example, the timer circuit 100 may receive the safety signal SS, and may output the second reset signal R2 via a port corresponding to the second reset signal R2 after a preset period of time (e.g., 3 seconds or the like) has elapsed from the point in time at which the safety signal SS is received.

In embodiments, the first reset signal R1 may set the timer circuit 100 to a reset state. In this case, the reset state of the timer circuit 100 may indicate that a count value of a timer, which is counting a certain period of time to generate the second reset signal R2, has been reset to zero. In some embodiments, the reset state of the timer circuit 100 may indicate that all operations of the timer circuit 100 have been halted and the count value of the timer, which is in the middle of counting, has been reset to zero.

In embodiments, the timer circuit 100 may implement the timer function based on a discharge state of at least one capacitor. In this case, the timer circuit 100 may transition to the reset state by fully discharging the capacitor upon receiving the first reset signal R1.

In embodiments, the switch control circuit 50 may include the latch circuit 200 configured to receive each of the safety signal SS, the enable signal EN, and the second reset signal R2, and to generate a retain signal RS. The switch control circuit 50 may include the latch circuit 200 configured to receive each of the safety signal SS and the enable signal EN, and to further receive the second reset signal R2 from the timer circuit 100, and to generate the retain signal RS.

The latch circuit 200 according to embodiments may receive the safety signal SS generated by the controller 40 via a port corresponding to the safety signal SS, receive the enable signal EN generated by the controller 40 via a port corresponding to the enable signal EN, and receive the second reset signal R2 via a port corresponding to the second reset signal R2.

In some embodiments, the enable signal EN input to the first logic circuit 300 may represent the enable signal EN generated by the controller 40. For example, the enable signal EN, which is input to the first logic circuit 300, may be input to the first logic circuit 300 through a signal transmission path formed via a contact point connected to an input terminal of the latch circuit 200.

In embodiments, the latch circuit 200 may output the retain signal RS from the point in time at which the safety signal SS is received until a point in time at which the second reset signal R2 is received. For example, the latch circuit 200 may receive the safety signal SS, store the state of the enable signal EN at the point in time at which the safety signal SS is received, and output the retain signal RS via a port corresponding to the retain signal RS, wherein the retain signal RS remains identical to the stored state of the enable signal EN from the point in time at which the safety signal SS is received until the point in time at which the second reset signal R2 is received via the port corresponding to the second reset signal R2.

As an example, when the state of the enable signal EN at the point in time at which the safety signal SS is received indicates a first state corresponding to an ON state of the switch 20, the latch circuit 200 may output the retain signal RS indicating the first state corresponding to the ON state of the switch 20 from the point in time at which the safety signal SS is received until the point in time at which the latch circuit 200 receives the second reset signal R2, even when the state of the enable signal EN applied to the latch circuit 200 after the safety signal SS is received indicates a second state corresponding to an OFF state of the switch 20.

In embodiments, the second reset signal R2 may set the latch circuit 200 to a reset state. In this case, the reset state of the latch circuit 200 may indicate that the stored state of the enable signal EN has been completely cleared. In some embodiments, the reset state of the latch circuit 200 may indicate that the latch circuit 200 has stopped outputting the retain signal RS and that the stored state of the enable signal EN has been completely cleared. In some embodiments, the stopping of the output of the retain signal RS by the latch circuit 200 may include stopping the output of the retain signal RS in the first state and outputting the retain signal RS in the second state.

In embodiments, the latch circuit 200 may implement the function of the latch circuit 200 by including a D flip-flop. In this case, the latch circuit 200 may transition to the reset state by clearing data stored in the D flip-flop at the point in time at which the second reset signal R2 is received.

In embodiments, the switch control circuit 50, which includes the timer circuit 100 and the latch circuit 200, may control the switch 20 or the switch driver for the switch 20 so that the switch 20 is maintained in the same state as before, in the event of a temporary fault in the controller 40 that primarily controls the operation of the switch 20 through the enable signal EN.

In embodiments, the controller 40 may diagnose the switch control circuit 50 based on the retain signal RS. In some embodiments, the controller 40 may diagnose the power supply apparatus including the switch control circuit 50 by diagnosing the switch control circuit 50 based on the retain signal RS.

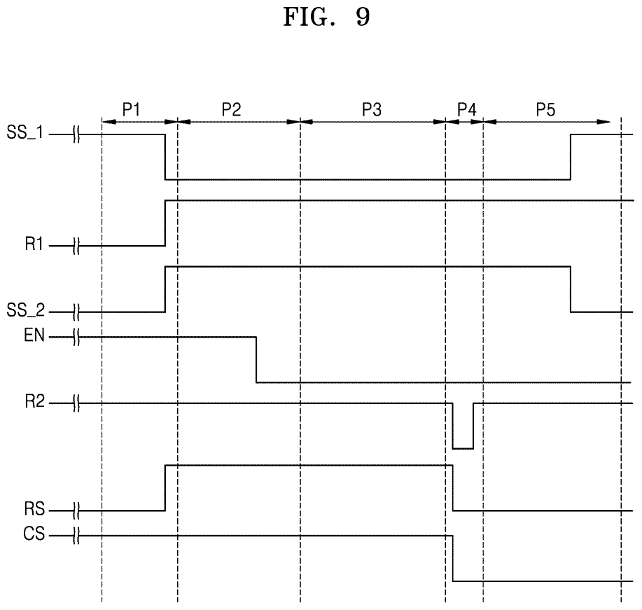

For example, the controller 40 may set at least one component (e.g., the timer circuit 100 and the latch circuit 200) constituting the switch control circuit 50 to the reset state by applying the first reset signal R1, and may then apply the safety signal SS. Thereafter, the controller 40 may determine whether the switch control circuit 50 is operating normally by determining whether the retain signal RS is output at a scheduled point in time. Specific diagnostic operations of the switch control circuit 50 performed by the controller 40 will be described in detail herein with reference to FIG. 9.

In some embodiments, for the stable operation of the switch control circuit 50, it is essential to reset at least some components of the switch control circuit 50. For example, the resetting of each component must precede the diagnostic process for determining whether the component operates normally after resetting.

According to the related art, in order to perform the reset as described herein, a dedicated port for outputting a separate reset signal was required in the controller 40. For example, as shown in FIG. 2, the main controller 41 required not only the port for outputting the enable signal EN, but also an additional port for outputting a separate reset signal generated by the main controller 41.

According to embodiments of the present disclosure, since a separate reset signal generated from the controller 40 is not used to reset at least some components of the switch control circuit 50, the complexity on a software side of the controller 40 can be reduced, and the number of ports that must be provided in the controller 40 can also be reduced. As a result, hardware requirements for the controller 40 can be reduced.

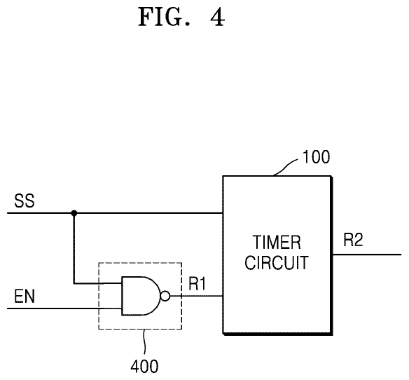

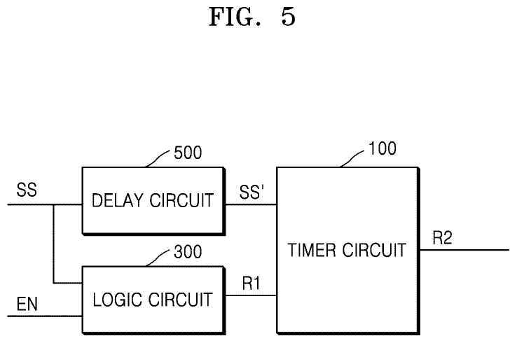

Hereinafter, specific implementation examples of the switch control circuit 50, in which the timer circuit 100 is implemented to receive the first reset signal R1 from the first logic circuit 300, will be described with reference to FIGS. 4 and 5.

FIG. 4 is a circuit diagram of a switch control circuit including a logic circuit configured to output the reset signal according to embodiments.

The switch control circuit 50 may include the first logic circuit 300 configured to receive the safety signal SS and the enable signal EN and to output the first reset signal R1, and the timer circuit 100 configured to receive the safety signal SS and the first reset signal R1 and to output the second reset signal R2.

In some embodiments, various signals used in the switch control circuit 50, such as the safety signal SS, the enable signal EN, and the first reset signal R1, may each indicate a plurality of states, and each state may be distinguished based on a voltage level of the signal. At this point, it would be readily understood by those skilled in the art that an active state of each signal may be defined as either a high state or a low state depending on a circuit design.

Referring to FIG. 4, the first logic circuit 300 may output the first reset signal R1 indicating an active state when at least one of the safety signal SS and the enable signal EN indicates an inactive state. For example, when the active states of both the safety signal SS and the enable signal EN are defined as high states, and the active state of the first reset signal R1 is also defined as the high state, the first logic circuit 300 may be implemented as a NAND gate 400.

That is, when the active states of both the safety signal SS and the enable signal EN are defined as high states, and the active state of the first reset signal R1 is also defined as the high state, the NAND gate 400 may output the first reset signal R1 in an inactive state while receiving both the safety signal SS and the enable signal EN in their active states. Conversely, when the NAND gate 400 receives the safety signal SS and/or the enable signal EN indicating inactive states, the NAND gate 400 may output the first reset signal R1 indicating an active state. Accordingly, when at least one of the safety signal SS indicating an inactive state and the enable signal EN indicating an inactive state is received, the NAND gate 400 may provide the first reset signal R1 in the active state to the timer circuit 100, thereby causing the timer circuit 100 to be set to a reset state.

In some embodiments, as described herein, the active state of each signal may be defined as the high state or the low state depending on the circuit design, and the first logic circuit 300 may be implemented to include at least one of various types of logic gates, in addition to the NAND gate 400, depending on how the active states of the respective signals are defined.

The timer circuit 100 may perform a reset process at a point in time at which the timer circuit 100 receives the first reset signal R1 in an active state. When the timer circuit 100 is implemented as a purely digital circuit, the reset may be completed within a few nanoseconds. However, when an analog circuit configuration is used, the reset may take from several microseconds to several milliseconds.

In some embodiments, the first reset signal R1 output from the first logic circuit 300 may experience a propagation delay depending on the characteristics of the logic gate. A single gate may typically experience a propagation delay on the order of a few nanoseconds.

In embodiments, in order for the timer circuit 100 to output the second reset signal R2 in an active state at a point in time after a preset period of time has elapsed since receiving the safety signal SS in an inactive state, the safety signal SS in the inactive state may be input to the timer circuit 100 after a certain period of time has elapsed since the timer circuit 100 received the first reset signal R1 in an active state.

Hereinafter, a specific implementation example of the switch control circuit 50 in which the timer circuit 100 is implemented to receive a delayed safety signal will be described with reference to FIG. 5.

FIG. 5 is a circuit diagram of a switch control circuit including a logic circuit and a delay circuit according to embodiments.

In embodiments, the timer circuit 100 may receive the safety signal SS after receiving the first reset signal R1, when the enable signal EN indicates an active state and the safety signal SS, which indicates an active state, transitions to an inactive state. For example, the timer circuit 100 may receive the first reset signal R1 in an inactive state while the enable signal EN and the safety signal SS are in the active states.

Subsequently, when the safety signal SS transitions from the active state to the inactive state, the timer circuit 100 may first receive the first reset signal R1 in the active state, and then receive the safety signal SS in the inactive state. Through this, the timer circuit 100 can perform the process of generating the second reset signal R2 based on the safety signal SS after completing the reset in a stable manner, thereby ensuring stable operation of the switch control circuit 50.

Referring to FIG. 5, the switch control circuit 50 may further include a delay circuit 500. The delay circuit 500 according to embodiments may transmit a delayed safety signal SS′ to the timer circuit 100.

In embodiments, the delay circuit 500 may be configured to receive the safety signal SS and delay the safety signal SS to input the delayed safety signal SS′ to the timer circuit 100. For example, the delay circuit 500 may generate the delayed safety signal SS′ by delaying the safety signal SS for a preset period of time.

In this case, the preset period of time may be set based on a time required for resetting the timer circuit 100 upon receiving the first reset signal R1 and a propagation delay time of the first logic circuit 300. For example, the preset period of time may be set to be greater than or equal to the sum of the time required for resetting the timer circuit 100 and the propagation delay time of the first logic circuit 300. Since the reset process of the timer circuit 100 and the logic gate constituting the first logic circuit 300 can be designed in various ways, those skilled in the art may set a delay time of the delay circuit 500 in consideration of the design of the reset process of the timer circuit 100 and the logic gate of the first logic circuit 300.

In embodiments, the delay circuit 500 may include circuit elements for delaying an input signal using various methods, such as a resistance-capacitance (RC) circuit including a resistor and a capacitor, at least one inverter or buffer gate arranged in series, a digital counter, or a combination thereof.

Through this, the timer circuit 100 can perform the process of generating the second reset signal R2 based on the delayed safety signal SS′ after completing the reset in a stable manner, thereby ensuring stable operation of the switch control circuit 50.

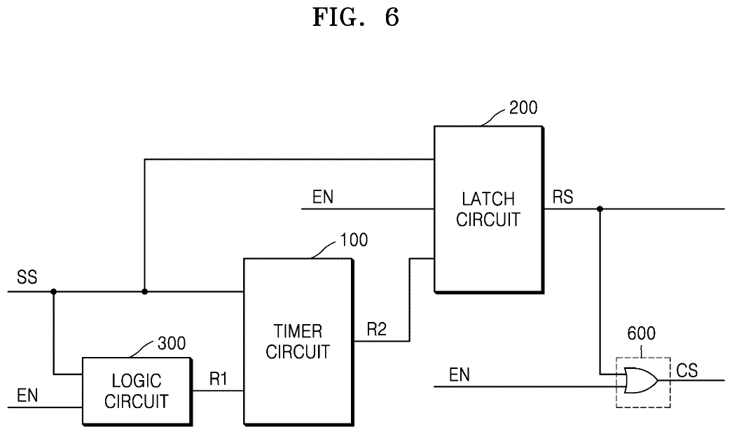

FIG. 6 is a circuit diagram of a switch control circuit including a logic circuit configured to receive the enable signal and the retain signal according to embodiments.

Referring to FIG. 6, a switch control circuit 50 according to embodiments may include the timer circuit 100, the latch circuit 200, the first logic circuit 300, and a second logic circuit 600.

In embodiments, the second logic circuit 600 may be configured to receive the enable signal EN and the retain signal RS, and to output a control signal CS for controlling opening and closing of the switch 20. The second logic circuit 600 according to embodiments may receive the enable signal EN and the retain signal RS as inputs and output the control signal CS.

In embodiments, the enable signal EN input to the second logic circuit 600 may represent the enable signal EN generated by the controller 40. For example, the enable signal EN, which is input to the second logic circuit 600, may be input to the second logic circuit 600 through a signal transmission path formed via a contact point connected to the input terminal of the latch circuit 200.

In the present disclosure, the control signal CS refers to a signal that is directly applied to the switch 20 to control the opening and closing of the switch 20, or applied to the switch driver for the switch 20 to control the opening and closing of the switch 20. In embodiments, the control signal CS may control the state of the switch 20 to an ON state or an OFF state. For example, the control signal CS indicating a first state may control the switch 20 to the ON state, and the control signal CS indicating a second state may control the switch 20 to the OFF state.

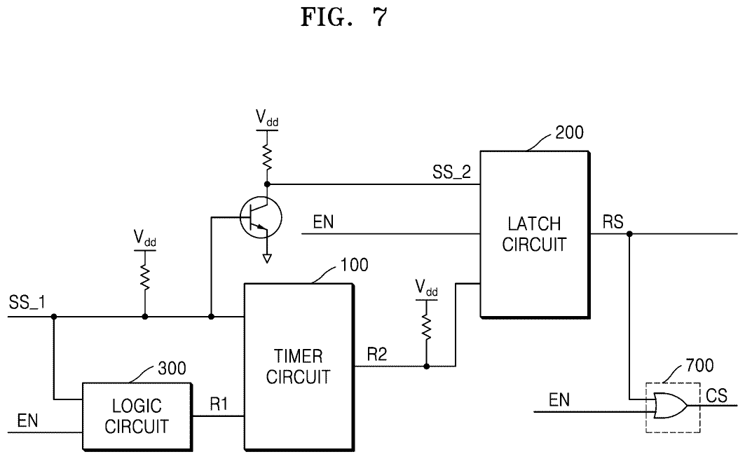

In embodiments, when active states of the enable signal EN, the retain signal RS, and the control signal CS are all defined as high states, the second logic circuit 600 may be implemented as an OR gate. For example, when at least one of the enable signal EN in a high state and the retain signal RS in the high state is input, the second logic circuit 600 may output the control signal CS in the high state to control the switch 20 to the ON state. FIG. 7 is a circuit diagram of a switch control circuit according to embodiments;

FIG. 7 illustrates an example of a section-by-section power supply scheme for implementing a stable switch control circuit 50. In another example, the section-by-section power supply scheme may be modified in various ways, and active states of respective signals for each component of the switch control circuit 50 may be defined differently depending on the power supply scheme. For example, those skilled in the art may adopt a power supply scheme different from that shown in FIG. 7, depending on various technical requirements and application fields.

Referring to FIG. 7, in the switch control circuit 50 according to embodiments, an active state of a safety signal SS_1 for the timer circuit 100 may be defined as a low state, and an active state of the first reset signal R1 may be defined as a high state.

In the switch control circuit 50 according to embodiments, active states of a safety signal SS_2, the enable signal EN, and the retain signal RS for the latch circuit 200 may be defined as high states, and an active state of the second reset signal R2 for the latch circuit 200 may be defined as a low state.

The switch control circuit 50 according to embodiments may include a second logic circuit 700 configured to receive, as inputs, the enable signal EN and the retain signal RS, whose active states are defined as high states, and to output the control signal CS.

The second logic circuit 700 according to embodiments may be implemented as an OR gate. For example, when at least one of the enable signal EN in a high state and the retain signal RS in the high state is input, the second logic circuit 700 may output the control signal CS in the high state to control the switch 20 to the ON state.

The switch control circuit 50 may operate in two modes. The modes of the switch control circuit 50 may include a normal operation mode for implementing safe control of the switch 20 in actual situations, and a diagnostic operation mode for verifying whether the switch control circuit 50 operates normally.

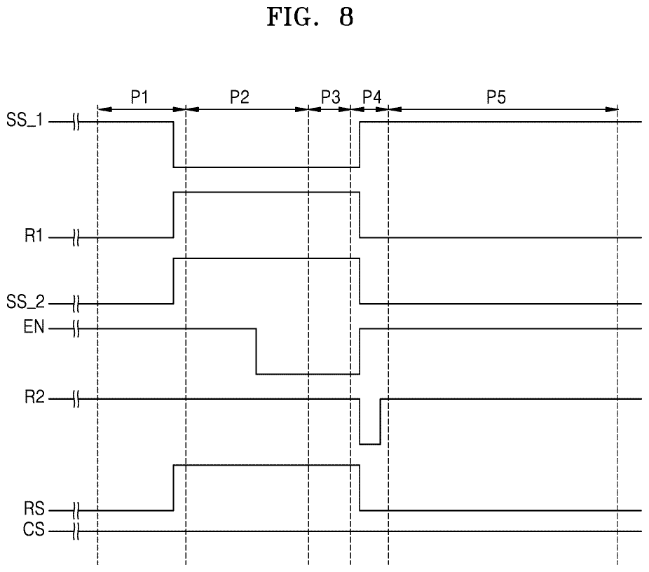

Hereinafter, with reference to FIGS. 8 and 9, operation processes of the switch control circuit 50, in which the active states are defined as in FIG. 7, will be described in detail according to each mode.

FIG. 8 is an exemplary diagram for describing a normal operation of the switch control circuit of FIG. 7.

Referring to FIG. 8, the normal operation of the switch control circuit 50 according to embodiments may be controlled based on the safety signal SS_1 and the enable signal EN.

Until a first time period P1, the safety signal SS_1 in a high state and the enable signal EN in the high state may be applied to the switch control circuit 50. Accordingly, the switch control circuit 50 may output the control signal CS in the high state based on the enable signal EN.

In the first time period P1, the controller 40 may output the safety signal SS_1 in a low state. In embodiments, the controller 40 may change the state of the safety signal SS_1 from the high state to the low state based on the occurrence of an abnormality in the controller 40. For example, the auxiliary controller 42 may change the state of the safety signal SS_1 from the high state to the low state based on the occurrence of an abnormality in the main controller 41 (e.g., a reset of the main controller 41).

In some embodiments, as the state of the safety signal SS_1 output from the controller 40 changes, the safety signal SS_2 input to the latch circuit 200 may change from the low state to the high state. In embodiments, as the safety signal SS_2 in the high state is input to the latch circuit 200, the latch circuit 200 may capture and store the high state indicated by the enable signal EN at a point in time at which the safety signal SS_2 is input, and may output the retain signal RS in the high state.

In embodiments, the state of the signal captured and stored by the latch circuit 200 at the point in time at which the safety signal SS_2 is input may be the state of the control signal CS. To this end, the latch circuit 200 may further include an input port corresponding to the control signal CS.

In some embodiments, as the state of the safety signal SS_1 output from the controller 40 changes, the first reset signal R1 output from the first logic circuit 300 may change from the low state to the high state. In embodiments, when the first logic circuit 300 implemented as the NAND gate 400 receives both the safety signal SS_1 and the enable signal EN in the high states, the first logic circuit 300 may output the first reset signal R1 in the low state. When at least one of the safety signal SS_1 and the enable signal EN is in the low state, the first logic circuit 300 may output the first reset signal R1 in the high state.

In this case, the timer circuit 100 that receives the first reset signal R1 in the high state may be set to a reset state. In some embodiments, as described herein with reference to FIG. 5, the timer circuit 100 may receive a delayed safety signal SS′ instead of receiving the changed state of the safety signal SS_1 immediately upon the state change of the safety signal SS_1. Through this, the timer circuit 100 may receive the delayed safety signal SS′ in the low state after a certain period of time has elapsed since receiving the first reset signal R1 in the high state.

In a second time period P2, the enable signal EN output from the controller 40 may change from the high state to the low state as a result of the occurrence of the abnormality in the controller 40. For example, the output of the enable signal EN in an active state may be interrupted as the main controller 41 performs an unexpected reset operation.

In this case, the state of the control signal CS may be maintained in the high state by the retain signal RS output from the latch circuit 200, and accordingly, the connection state of the switch 20 may be maintained regardless of the occurrence of the abnormality in the controller 40.

In a third time period P3, the controller 40 may be restarted through a reset operation, and the state of the control signal CS may be maintained in the high state by the retain signal RS output from the latch circuit 200, so that the connection state of the switch 20 may also be maintained.

In a fourth time period P4, as the abnormality in the controller 40 is resolved, the controller 40 may change the state of the safety signal SS_1 from the low state to the high state and may output the enable signal EN in the high state. In some embodiments, as the state of the safety signal SS_1 output from the controller 40 changes, the safety signal SS_2 input to the latch circuit 200 may change from the high state to the low state.

Simultaneously with or after this, the second reset signal R2 in an active state may be input to the latch circuit 200, and the latch circuit 200 may continue to output the retain signal RS in the high state until the second reset signal R2 is input. That is, the control signal CS may also remain in the high state until the second reset signal R2 is input.

For example, as a preset period of time elapses from a point in time at which the safety signal SS_1 in the low state is input to the timer circuit 100 in the first time period P1, the timer circuit 100 may output the second reset signal R2 in the low state in the fourth time period P4. At this time, a point in time at which the second reset signal R2 is output may be the same as a point in time at which the safety signal SS_2 changes from the high state to the low state, but may also be a point in time after that.

As the latch circuit 200 receives the second reset signal R2 in the low state, the latch circuit 200 may be reset, the stored state of the enable signal EN may be cleared, and the retain signal RS may change to the low state.

In some embodiments, as the enable signal EN in the high state is normally generated by the controller 40, the control signal CS may be maintained in the high state even when the retain signal RS changes to the low state.

In a fifth time period P5, as the safety signal SS_1 in the high state and the enable signal EN in the state are applied to the switch control circuit 50, the switch control circuit 50 may stably control the switch 20 as in the time before the first time period P1.

FIG. 9 is an exemplary diagram for describing a diagnostic operation of the switch control circuit of FIG. 7.

Referring to FIG. 9, the diagnostic operation of the switch control circuit 50 according to embodiments may be controlled based on the safety signal SS_1 and the enable signal EN. That is, the diagnostic operation of the switch control circuit 50 may be performed without using a separate reset signal distinct from the safety signal SS_1 or the enable signal EN generated by the controller 40.

Until a first time period P1, the safety signal SS_1 in a high state and the enable signal EN in the high state may be applied to the switch control circuit 50. Accordingly, the switch control circuit 50 may output the control signal CS in the high state based on the enable signal EN.

In the first time period P1, the controller 40 may generate the safety signal SS_1 in a low state. In embodiments, the controller 40 may output the safety signal SS_1 in the low state based on a user input instructing the diagnostic operation or based on a preset condition being satisfied, that is, based on the start of a diagnostic operation mode. For example, when the power supply system 1 is implemented as a vehicle system such as an electric vehicle, the preset condition may include the reception, by the controller 40, of a command to shut down vehicle operation.

In this case, the output of the safety signal SS_1 in the low state does not actually indicate that an abnormality has occurred in the main controller 41, but rather means that the safety signal SS_1 in the low state is artificially output for the purpose of the diagnostic operation.

As the state of the safety signal SS_1 output from the controller 40 changes, the safety signal SS_2 input to the latch circuit 200 may change from the low state to the high state. In embodiments, as the safety signal SS_2 in the high state is input to the latch circuit 200, the latch circuit 200 may capture and store the high state indicated by the enable signal EN at a point in time at which the safety signal SS_2 is input, and may output the retain signal RS in the high state.

In some embodiments, as the state of the safety signal SS_1 output from the controller 40 changes, the first reset signal R1 output from the first logic circuit 300 may change from the low state to the high state. In embodiments, when the first logic circuit 300 implemented as the NAND gate 400 receives both the safety signal SS_1 and the enable signal EN in the high states, the first logic circuit 300 may output the first reset signal R1 in the low state. When at least one of the safety signal SS_1 and the enable signal EN is in the low state, the first logic circuit 300 may output the first reset signal R1 in the high state.

In this case, the timer circuit 100 that receives the first reset signal R1 in the high state may be set to a reset state. In some embodiments, as described herein with reference to FIG. 5, the timer circuit 100 may receive a delayed safety signal SS′ instead of receiving the changed state of the safety signal SS_1 immediately upon the state change of the safety signal SS_1. Through this, the timer circuit 100 may receive the delayed safety signal SS′ in the low state after a certain period of time has elapsed since receiving the first reset signal R1 in the high state.

By inputting the first reset signal R1 in the high state to the timer circuit 100, the timer circuit 100 may be set to a reset state, which means that at least some components of the switch control circuit 50 are set to a reset state in order to diagnose whether the switch control circuit 50 is operating normally.

In a second time period P2, the controller 40 may change the enable signal EN from the high state to the low state. For example, the controller 40 may stop the output of the enable signal EN in the high state based on the start of the diagnostic operation caused by the reception of a command to shut down vehicle operation. In some embodiments, the controller 40 may maintain the enable signal EN in the high state during the second time period P2.

In this case, the state of the control signal CS may be maintained in the high state due to the retain signal RS output from the latch circuit 200, and accordingly, the connection state of the switch 20 may be maintained regardless of the output of the enable signal EN from the controller 40.

In a third time period P3, the latch circuit 200 may maintain the output of the retain signal RS in the high state based on the absence of an input of the second reset signal R2 in an active state. Accordingly, both the enable signal EN and the retain signal RS may indicate the high state, and the control signal CS may also indicate the high state.

In a fourth time period P4, as a preset period of time elapses from a point in time at which the safety signal SS_1 in the low state is input to the timer circuit 100 in the first time period P1, the timer circuit 100 may output the second reset signal R2 in the low state. As the timer circuit 100 outputs the second reset signal R2 in the low state, the second reset signal R2 in the low state may be input to the latch circuit 200.

As the latch circuit 200 receives the second reset signal R2 in the low state, the latch circuit 200 may be reset, the stored state of the enable signal EN may be cleared, and the retain signal RS may change to the low state.

In some embodiments, when the controller 40 stops the output of the enable signal EN in the high state, the control signal CS may change to the low state as the retain signal RS changes to the low state.

The controller 40 may obtain the retain signal RS output from the latch circuit 200. The controller 40 may diagnose whether the switch control circuit 50, which includes the timer circuit 100 and the latch circuit 200, is operating normally based on whether the retain signal RS changes to the high state at the point in time at which the safety signal SS_1 in the low state is output, whether the high state of the retain signal RS is maintained for a certain period of time with respect to the timer circuit 100, and/or whether the retain signal RS changes to the low state after a preset period of time has elapsed with respect to the timer circuit 100.

For example, the controller 40 may diagnose that the switch control circuit 50 is operating normally when the retain signal RS changes to the high state at the point in time at which the safety signal SS_1 in the low state is output, the high state of the retain signal RS is maintained for a preset period of time with respect to the timer circuit 100, and the retain signal RS changes to the low state at a point in time after the certain period of time has elapsed with respect to the timer circuit 100.

In a fifth time period P5, the controller 40 may change the safety signal SS_1 from the low state to the high state based on the completion of the diagnosis of the switch control circuit 50. As the state of the safety signal SS_1 output from the controller 40 changes, the safety signal SS_2 input to the latch circuit 200 may change from the low state to the high state.

According to the herein-described problem solving means of the present disclosure, at least some components of a switch control circuit can be reset without using a reset signal individually generated from a controller configured to control the switch control circuit through signal output, thereby reducing software complexity of the controller.

In addition, according to the herein-described problem-solving means of the present disclosure, a controller configured to control a switch control circuit through signal output need not include a port for outputting an individually generated reset signal, thereby reducing hardware requirements for the controller.

The effects according to embodiments of the present disclosure are not limited to the herein-mentioned effects, and other effects not mentioned may be clearly understood by those skilled in the art from the description of the present specification.

The use of all examples or exemplary terms (for example, and the like) in the present disclosure is to simply describe the present disclosure in detail, and unless the range of the present disclosure is not limited by the examples or the exemplary terms unless limited by the claims. Also, numerous modifications and adaptations will be readily apparent to one of ordinary skill in the art without departing from the spirit and scope of the present disclosure.

Therefore, it should be noted that the spirit of the present disclosure is not limited to the embodiments described herein, and not only the claims to be described herein, but also all ranges equivalent to or equivalently changed from the claims fall within the scope of the spirit of the present disclosure.

What is claimed is:

1. A switch control apparatus comprising:
a controller configured to generate a safety signal and an enable signal;
a first logic circuit configured to receive the safety signal and the enable signal, and to generate a first reset signal;
a timer circuit configured to receive each of the safety signal and the first reset signal, and to generate a second reset signal; and
a latch circuit configured to receive each of the safety signal, the enable signal, and the second reset signal, and to generate a retain signal.

2. The switch control apparatus of claim 1, wherein the first logic circuit is further configured to output the first reset signal indicating an active state when at least one of the safety signal and the enable signal indicates an inactive state.

3. The switch control apparatus of claim 1, wherein the timer circuit is further configured to receive the safety signal after receiving the first reset signal when the enable signal indicates an active state and the safety signal indicating the active state transitions to an inactive state.

4. The switch control apparatus of claim 3, further comprising a delay circuit configured to transmit a delayed safety signal to the timer circuit.

5. The switch control apparatus of claim 1, wherein the controller includes:
a main controller configured to generate the enable signal; and
an auxiliary controller configured to generate the safety signal based on a state of the main controller.

6. The switch control apparatus of claim 1, wherein
the first reset signal causes the timer circuit to be set to a reset state, and
the second reset signal causes the latch circuit to be set to the reset state.

7. The switch control apparatus of claim 1, wherein the timer circuit is further configured to output the second reset signal at a point in time after a preset period of time has elapsed from a point in time at which the safety signal is received.

8. The switch control apparatus of claim 1, wherein the latch circuit is further configured to output the retain signal from a point in time at which the safety signal is received until a point in time at which the second reset signal is received.

9. The switch control apparatus of claim 1, further comprising a second logic circuit configured to receive the enable signal and the retain signal, and to output a control signal for controlling opening and closing of a switch.

10. The switch control apparatus of claim 1, wherein the controller is further configured to diagnose the switch control apparatus based on the retain signal.

11. A power supply apparatus comprising:
a power source;
a switch configured to electrically connect or disconnect the power source to or from at least one load;
a controller configured to generate a safety signal and an enable signal;
a first logic circuit configured to receive the safety signal and the enable signal, and to generate a first reset signal;
a timer circuit configured to receive each of the safety signal and the first reset signal, and to generate a second reset signal;
a latch circuit configured to receive each of the safety signal, the enable signal, and the second reset signal, and to generate a retain signal; and
a second logic circuit configured to receive the enable signal and the retain signal, and to output a control signal for controlling opening and closing of the switch.

12. The power supply apparatus of claim 11, wherein the first logic circuit is further configured to output the first reset signal indicating an active state when at least one of the safety signal and the enable signal indicates an inactive state.

13. The power supply apparatus of claim 11, wherein the timer circuit is further configured to receive the safety signal after receiving the first reset signal when the enable signal indicates an active state and the safety signal indicating the active state transitions to an inactive state.

14. The power supply apparatus of claim 13, further comprising a delay circuit configured to transmit a delayed safety signal to the timer circuit.

15. The power supply apparatus of claim 11, wherein the controller includes:
a main controller configured to generate the enable signal; and
an auxiliary controller configured to generate the safety signal based on a state of the main controller.

16. The power supply apparatus of claim 11, wherein
the first reset signal causes the timer circuit to be set to a reset state, and
the second reset signal causes the latch circuit to be set to the reset state.

17. The power supply apparatus of claim 11, wherein the timer circuit is further configured to output the second reset signal at a point in time after a preset period of time has elapsed from a point in time at which the safety signal is received.

18. The power supply apparatus of claim 11, wherein the latch circuit is further configured to output the retain signal from a point in time at which the safety signal is received until a point in time at which the second reset signal is received.

19. The power supply apparatus of claim 11, wherein the controller is further configured to diagnose the power supply apparatus based on the retain signal.
